(19) United States
(12) Patent Application Publication
(10) Pub. No.: US 2026/0032899 A1
(43) Pub. Date: Jan. 29, 2026

(54) SEMICONDUCTOR MEMORY DEVICE AND MANUFACTURING METHOD OF THE SEMICONDUCTOR MEMORY DEVICE

(71) Applicant: SK hynix Inc., Icheon-si Gyeonggi-do (KR)

(72) Inventors: Hyun Kyu LEE, Icheon-si Gyeonggi-do (KR); Sun Kak HWANG, Icheon-si Gyeonggi-do (KR); Sung Soon KIM, Icheon-si Gyeonggi-do (KR)

(73) Assignee: SK hynix Inc., Icheon-si Gyeonggi-do (KR)

(21) Appl. No.: 19/051,871

(22) Filed: Feb. 12, 2025

(30) Foreign Application Priority Data
Jul. 25, 2024 (KR) 10-2024-0098779

(51) Int. Cl. H10B 41/27; G11C 16/04; H10B 41/10; H10B 43/10; H10B 43/27

(52) U.S. Cl. CPC H10B 41/27; G11C 16/0483; H10B 41/10; H10B 43/10; H10B 43/27

(57) ABSTRACT

The present disclosure relates to a semiconductor memory device and a method of manufacturing the semiconductor memory device. The semiconductor memory device includes a core insulating layer, a semiconductor structure including a channel portion on a side wall of the core insulating layer and a capping portion covering one surface of the core insulating layer and coupled to the channel portion, a plurality of conductive layers and a plurality of insulating layers surrounding a side wall of the semiconductor structure, each of the plurality of conductive layers and each of the plurality of insulating layers alternating with each other, and a memory layer disposed between each of the plurality of conductive layers and the semiconductor structure.

### CROSS-REFERENCE TO RELATED APPLICATION

The present application claims priority under 35 U.S.C. § 119 (a) to Korean patent application number 10-2024-0098779 filed on Jul. 25, 2024, in the Korean Intellectual Property Office, the entire contents of which application is incorporated herein by reference.

### BACKGROUND

### 1. Technical Field

Various embodiments of the present disclosure generally relate to a semiconductor memory device of an electronic system, and more particularly, to a semiconductor memory device including a three-dimensional memory cell array and a method of manufacturing the semiconductor memory device.

### 2. Related Art

Semiconductor memory devices are applicable to electronic devices in various fields such as automobiles, medical care, and data centers, as well as small electronic devices. As a result, there has been an increasing demand for semiconductor memory devices.

A semiconductor memory device may include a memory cell array, and the memory cell array may include a plurality of memory cells for storing data. Non-volatile memory devices may be divided into a two-dimensional semiconductor memory device including a two-dimensional memory cell array and a three-dimensional semiconductor memory device including a three-dimensional memory cell array.

A plurality of memory cells of the three-dimensional memory cell array may be stacked in a vertical direction crossing a substrate. Therefore, as compared to the two-dimensional cell array including a plurality of memory cells arranged next to each other over the substrate, the three-dimensional cell array may be more advantageous for large-capacity semiconductor memory devices.

The plurality of memory cells of the three-dimensional memory cell array may form a plurality of memory cell strings. Each of the memory cell strings may include memory cells coupled in series. The memory cells of each of the memory cell strings may be coupled in series by a semiconductor structure of a cell pillar extending in a vertical direction. As more memory cells forming each memory cell string are stacked, operational reliability may be deteriorated.

### SUMMARY

According to an embodiment, a semiconductor memory device may include a core insulating layer extending in a first direction, a semiconductor structure including a channel portion extending in the first direction on a side wall of the core insulating layer and including a capping portion coupled to the channel portion, the capping portion covering a top surface of the core insulating layer, an oxidized buffer layer interposed between the channel portion of the semiconductor structure and the core insulating layer, the oxidized buffer layer including a metal oxide, a plurality of conductive layers and a plurality of insulating layers alternately stacked with each other in the first direction, each of the plurality of conductive layers and the plurality of insulating layers surrounding a side wall of the semiconductor structure, and a memory layer disposed between each of the plurality of conductive layers and the semiconductor structure.

According to an embodiment, a method of manufacturing a semiconductor memory device may include stacking a plurality of first material layers and a plurality of second material layers stacked on top of each other in a first direction, each of the plurality of first material layers and each of the plurality of second material layers alternating with each other, forming an opening extending in the first direction to pass through the plurality of first material layers and the plurality of second material layers, forming a memory layer on an inner wall of the opening, forming an amorphous semiconductor layer on an inner wall of the memory layer, forming metal catalysts on an inner wall of the amorphous semiconductor layer, crystalizing the amorphous semiconductor layer into a crystalline semiconductor layer, forming a buffer layer on an inner wall of the crystalline semiconductor layer, performing a gettering process on the metal catalysts, and forming an oxidized buffer layer by oxidizing the buffer layer exposed after the gettering process.

### BRIEF DESCRIPTION OF THE DRAWINGS

FIG. 1 is a circuit diagram illustrating a memory cell array of a semiconductor memory device according to an embodiment of the present disclosure;

FIGS. 2A and 2B are diagrams illustrating a semiconductor memory device according to embodiments of the present disclosure;

FIGS. 3A and 3B are diagrams illustrating a memory cell array according to an embodiment of the present disclosure;

FIG. 4 is a flowchart illustrating manufacturing processes of a semiconductor memory device according to various embodiments of the present disclosure;

FIG. 5 is a cross-sectional diagram illustrating a preliminary stack structure, an opening, and a memory layer according to an embodiment of the present disclosure;

FIG. 6 is a flowchart illustrating an embodiment of ST7 shown in FIG. 4;

FIGS. 7A, 7B, and 7C are cross-sectional diagrams illustrating various embodiments of an amorphous semiconductor layer, a buffer layer, metal catalysts, and a crystalline semiconductor layer;

FIG. 8 is a flowchart illustrating an embodiment of ST7D shown in FIG. 6;

FIGS. 9A, 9B, and 9C are cross-sectional diagrams illustrating various embodiments of structures disposed in openings according to processes as shown in FIG. 8;

FIG. 10 is a flowchart illustrating embodiments for subsequent processes after ST7D shown in FIG. 6;

FIGS. 11A, 11B, 11C, 11D, and 11E are cross-sectional diagrams illustrating various embodiments of structures disposed in an opening according to a process A shown in FIG. 10, and FIG. 11F is a cross-sectional diagram illustrating various embodiments of a gate stack structure;

FIGS. 12A, 12B, and 12C are cross-sectional diagrams illustrating various embodiments of structures disposed in an opening according to a process B shown in FIG. 10, and FIG. 12D is a cross-sectional diagram illustrating various embodiments of a gate stack structure; and

FIG. 13 is a block diagram illustrating an electronic system according to an embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Terms such as “first” and “second” are used to distinguish between various elements and do not imply size, order, priority, quantity, or importance of the elements. For example, a first element may be named as a second element in one example, and the second element may be named as a first element in another example. The cross-hatching throughout the figures illustrates corresponding or similar areas between the figures rather than indicating the materials for the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout.

Various embodiments relate to a semiconductor memory device capable of improving operational reliability and a method of manufacturing the semiconductor memory device.

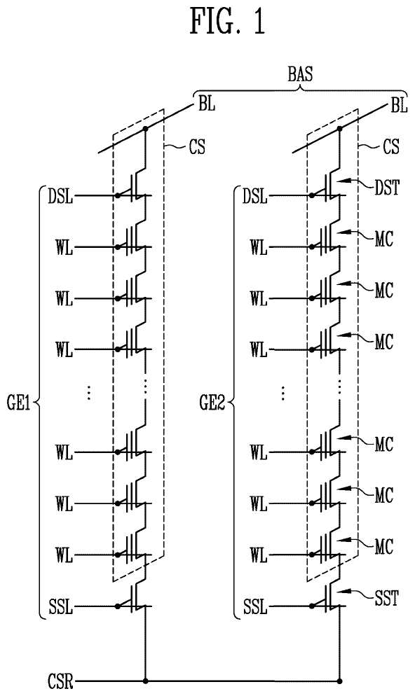

FIG. 1 is a circuit diagram illustrating a memory cell array of a semiconductor memory device according to an embodiment of the present disclosure.

Referring to FIG. 1, the memory cell array of the semiconductor memory device may include a plurality of memory cell strings CS. The plurality of memory cell strings CS may be connected to gate arrays GE1 and GE2, a bit line array BAS, and a common source layer CSR.

Each of the memory cell strings CS may include at least one source select transistor SST, a plurality of memory cells MC, and at least one drain select transistor DST. The plurality of memory cells MC may be coupled in series between the source select transistor SST and the drain select transistor DST. The source select transistor SST, the plurality of memory cells MC, and the drain select transistor DST may be coupled in series by a semiconductor structure of a cell pillar.

The gate array may include a plurality of gate groups. According to an embodiment, the gate array may include a first gate group GE1 and a second gate group GE2. Each of the first and second groups GE1 and GE2 may include a source select line SSL, a plurality of word lines WL, and a drain select line DSL. The source select line SSL may serve as a gate electrode of the source select transistor SST. Each of the word lines WL may serve as a gate electrode of the memory cell MC corresponding thereto. The drain select line DSL may serve as a gate electrode of the drain select transistor DST.

The bit line array BAS may include a plurality of bit lines BL. A voltage for precharging a channel of the memory cell string CS corresponding thereto may be applied to each of the bit lines BL. A voltage may be applied to the common source layer CSR to discharge a channel potential of the memory cell string CS.

The plurality of memory cell strings CS may be connected in parallel with the common source layer CSR. The plurality of memory cell strings CS may be divided into a plurality of rows and a plurality of columns. Memory cell strings in a column corresponding to each bit line BL may be connected in parallel to the bit line. Memory cell strings in a row corresponding to each gate group GE1 or GE2 may be connected in parallel to the corresponding gate group.

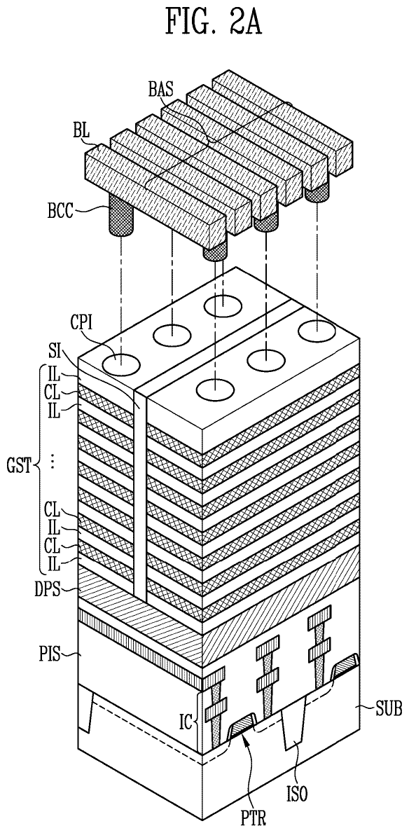

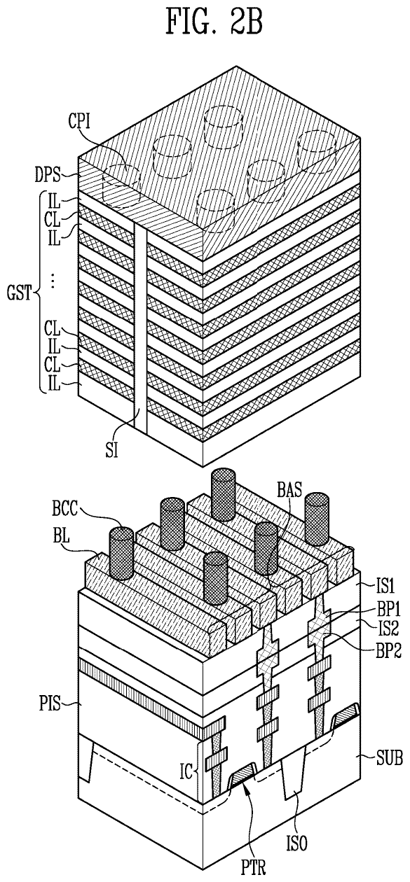

FIGS. 2A and 2B are diagrams illustrating a semiconductor memory device according to embodiments of the present disclosure.

Referring to FIGS. 2A and 2B, each of the first and second gate groups GE1 and GE2 as described above with reference to FIG. 1 may include a plurality of conductive layers CL of a corresponding one of a plurality of gate stack structures GST. Each of the conductive layers CL may include various conductive materials such as a doped semiconductor layer, a metal layer, and the like. The doped semiconductor layer may include a doped silicon layer. The metal layer may include tungsten, copper, molybdenum, or the like. The conductive layer CL may further include a conductive metal nitride layer. The conductive metal nitride layer may include a tantalum nitride, a tantalum nitride, or the like.

The gate stack structure GST may be arranged between the bit line array BAS and a doped semiconductor structure DPS. The gate stack structure GST may further include a plurality of insulating layers IL which are stacked alternately with the plurality of conductive layers CL between the bit line array BAS and the doped semiconductor structure DPS. Each of the insulating layers IL may include an insulating material such as a silicon oxide layer or a silicon oxynitride layer.

The doped semiconductor structure DPS may include at least one doped semiconductor layer. The doped semiconductor layer of the doped semiconductor structure DPS may include n type impurities or p type impurities. According to an embodiment, the doped semiconductor structure DPS may include at least one of a first conductivity type doped semiconductor layer including n type impurities as majority carriers and a second conductivity type doped semiconductor layer including p type impurities as majority carriers. The first conductivity type doped semiconductor layer may be provided as the common source layer CSR as described above with reference to FIG. 1, and the second conductivity type doped semiconductor layer may be provided as a well region.

The plurality of bit lines BL of the bit line array BAS may be separated from the gate stack structure GST. Each of the bit lines BL may be coupled to a cell pillar CPI through a bit line coupling structure BCC corresponding thereto. The bit line coupling structure BCC may be a conductive pattern and be formed with various configurations. The cell pillar CPI may extend from the doped semiconductor structure DPS toward the bit line BL to pass through the gate stack structure GST.

Neighboring gate stack structures GST may be separated from each other by a slit SI. A filling material disposed in the slit SI may be designed variously. According to an embodiment, the filling material may include an insulating material. According to another embodiment, the filling material may further include one or more of a conductive layer and a semiconductor layer in addition to the insulating layer.

The plurality of conductive layers CL of the gate stack structure GST may extend in a direction crossing the plurality of bit lines BL. At least one of the plurality of conductive layers CL which is adjacent to the doped semiconductor structure DPS may serve as the source select line SSL shown in FIG. 1. At least one of the conductive layers CL which is adjacent to the bit line array BAS may serve as the drain select line DSL shown in FIG. 1. The remaining conductive layers CL may serve as the plurality of word lines WL.

The plurality of conductive layers CL and the plurality of insulating layers IL of the gate stack structure GST may extend to surround a plurality of cell pillars CPI. Each of the cell pillars CPI may include a semiconductor structure which serves as a channel of the cell memory string CS as described above with reference to FIG. 1. The semiconductor structure of the cell pillar CPI may be electrically coupled to the corresponding bit line BL via the bit line coupling structure BCC. The semiconductor structure of the cell pillar CPI may include a contact surface which comes in contact with the doped semiconductor structure DPS. The contact surface may be defined on a portion of a sidewall of the cell pillar CPI or an end portion of the cell pillar CPI. According to an embodiment, referring to FIG. 2B, the doped semiconductor structure DPS may include a groove into which the end portion of the cell pillar CPI is inserted. A contact surface between the doped semiconductor structure DPS and the channel layer may be defined at the end portion of the cell pillar CPI.

Referring to FIGS. 2A and 2B, the cell string of the semiconductor memory device may be defined along the cell pillar CPI. The semiconductor memory device may further include a peripheral circuit structure for controlling operations of the memory cell string. The peripheral circuit structure may include an input/output circuit, a control circuit, a voltage generating circuit, a row decoder, a column decoder, a page buffer, and the like. More specifically, the peripheral circuit structure may include a plurality of transistors PTR, a capacitor, a resistor, and the like. FIGS. 2A and 2B illustrate the plurality of transistors PTR, which constitute a page buffer connected to the bit line array BAS, as a representative example. However, the peripheral circuit structure is not limited thereto.

The peripheral circuit structure including the plurality of transistors PTR may be adjacent to the doped semiconductor structure DPS as shown in FIG. 2A, or may be adjacent to the bit line array BAS as shown in FIG. 2B.

The peripheral circuit structure may be connected to the memory cell string via the plurality of conductive layers CL, the bit line array BAS, and the doped semiconductor structure DPS. According to an embodiment, the transistor PTR of the page buffer may be connected to the semiconductor structure of the cell pillar CPI via the corresponding bit line BL.

Each transistor PTR may be arranged in an active region of a semiconductor substrate SUB divided by an isolation layer ISO. The transistor PTR may be covered by a peripheral insulation structure PIS on the semiconductor substrate SUB. The transistor PTR may be connected to the bit line BL via an interconnection IC corresponding thereto. The interconnection IC may be formed in the peripheral insulation structure PIS. The interconnection IC may include one or more of a plurality of conductive lines and a plurality of conductive contacts for electrical connections.

Referring to FIG. 2A, the doped semiconductor structure DPS may be disposed over the peripheral insulation structure PIS. Though not shown, the interconnection IC may be electrically coupled to the bit line BL via a peripheral circuit contact between the bit line BL and the interconnection IC.

Referring to FIG. 2B, a first conductive bonding structure BP1 and a second conductive bonding structure BP2 may be disposed between the bit line array BAS and the interconnection IC. The first conductive bonding structure BP1 may be disposed in a first intervening insulation structure IS1 between the bit line array BAS and the peripheral insulation structure PIS. The first conductive bonding structure BP1 may be connected to the bit line BL corresponding thereto. The second conductive bonding structure BP2 may be disposed in a second intervening insulation structure IS2 between the first intervening insulation structure IS1 and the peripheral insulation structure PIS. The second conductive bonding structure BP2 may be connected to the interconnection IC corresponding thereto. The interconnection IC and the bit line BL may be electrically coupled to each other by bonding between the first conductive bonding structure BP1 and the second conductive bonding structure BP2.

Referring to FIG. 2A or 2B, the cell pillar CPI may include a memory layer which extends on an outer wall of the semiconductor structure. Hereinafter, a memory cell array of a semiconductor memory device according to various embodiments of the present disclosure will be described with reference to the cross section of the gate stack structure GST and the cross section of the cell pillar CPI.

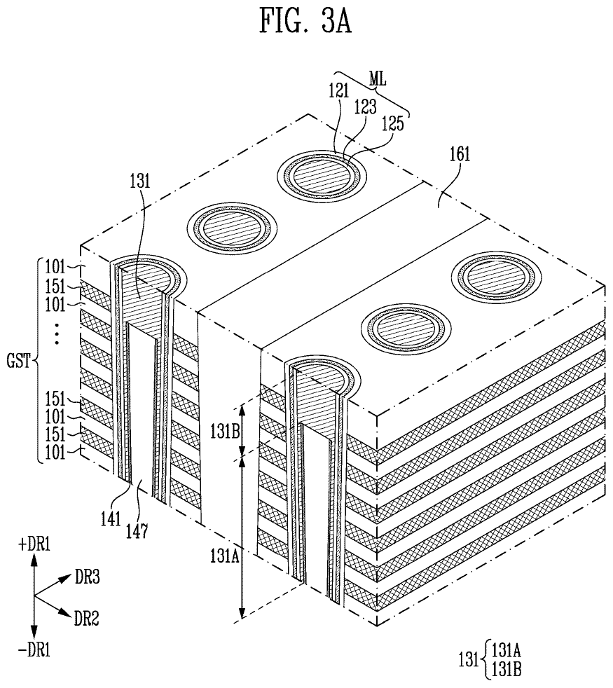

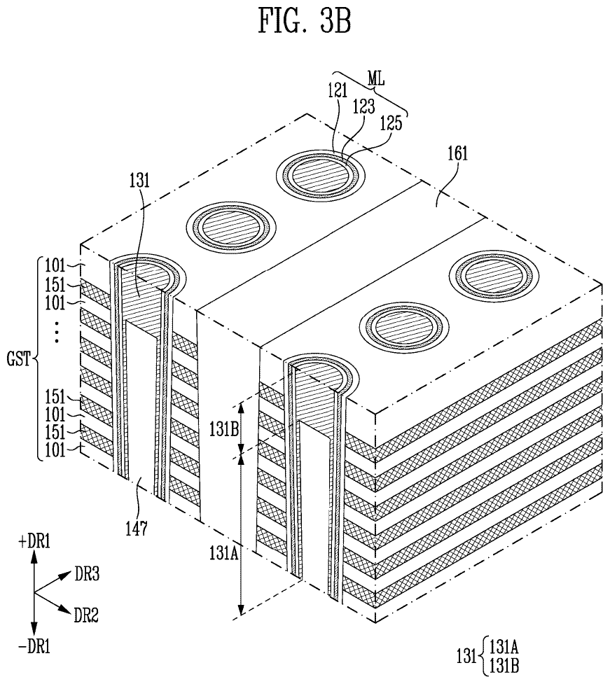

FIGS. 3A and 3B are diagrams illustrating a memory cell array according to an embodiment of the present disclosure.

Referring to FIGS. 3A and 3B, the cell pillar CPI shown in FIGS. 2A and 2B may include a memory layer ML, a semiconductor structure 131, and a core insulating layer 147. Referring to FIG. 3A, the cell pillar CPI shown in FIGS. 2A and 2B may further include an oxidized buffer layer 141.

Referring to FIGS. 3A and 3B, the core insulating layer 147 may extend in a first direction +DR1. The first direction +DR1 may be defined as a direction in which the gate stack structure GST faces the bit line array BAS shown in FIGS. 2A and 2B.

The semiconductor structure 131 may include a crystallized semiconductor material. In an embodiment, the crystallized semiconductor material of the semiconductor structure 131 may be provided using metal induced crystallization (MIC) which is advantageous for uniform crystallization. The crystallized semiconductor material of the semiconductor structure 131 may include silicon (Si), germanium (Ge), or a mixture thereof which serves as a channel of a memory cell string. According to an embodiment, the semiconductor structure 131 may include polycrystalline silicon.

The semiconductor structure 131 may include a channel portion 131A and a capping portion 131B. The channel portion 131A may extend in the first direction +DR1 on a sidewall of the core insulating layer 147. According to an embodiment, the channel portion 131A may surround a sidewall of the core insulating layer 147. The capping portion 131B may be coupled to the channel portion 131A and cover one surface of the core insulating layer 147 toward a first direction +DR1. In an embodiment, the capping portion 131B may be directly coupled to the channel portion 131A and cover one surface of the core insulating layer 147 toward a first direction +DR1. In an embodiment, the capping portion 131B may be coupled to the channel portion 131A and cover a first surface of the core insulating layer 147. For example, the capping portion 131B may be coupled to the channel portion 131A and extends to cover a top surface of the core insulating layer 147 as shown in FIGS. 3A and 3B. In an embodiment, the capping portion 131B may be in contact with the top surface of the core insulating layer 147. In an embodiment, the first surface (i.e., top surface) of the core insulating layer 147 may face the capping portion 131B in the first direction +DR1. For example, the first surface (i.e., top surface) of the core insulating layer 147 may face the capping portion 131B in the first direction +DR1 as shown in FIGS. 3A and 3B. The capping portion: 131B may include a doped semiconductor. The doped semiconductor of the capping portion 131B may include n type impurities, or both n type impurities and p type impurities. According to an embodiment, the capping portion 131B may include n type impurities as major carriers and be provided as a drain region. The capping portion 131B may be electrically coupled to a bit line corresponding thereto via the bit line coupling structure BCC shown in FIG. 2A or 2B. The channel portion 131A may be interposed between the memory layer ML and the core insulating layer 147. A portion of the channel portion 131A adjacent to the capping portion 131B may include n type impurities or both n and p type impurities to provide a first junction overlap region. According to an embodiment, the first junction overlap region of the channel portion 131A may include n type impurities as majority carriers. A depth of the first junction overlap region may be defined from the capping portion 131B toward a direction-DR1 opposite to the first direction +DR1. The depth of the first junction overlap region may be variously designed and controlled so as not to reach levels at which the plurality of word lines WL as described above with reference to FIG. 1 are disposed. Though not shown in FIGS. 3A and 3B, the channel portion 131A may extend toward the doped semiconductor structure DPS shown in FIG. 2A or 2B. According to an embodiment, the channel portion 131A may extend into the doped semiconductor structure DPS.

The channel portion 131A of the semiconductor structure 131 may include a contact surface which contacts the doped semiconductor structure DPS shown in FIG. 2A or 2B. Another portion of the channel portion 131A adjacent to the capping portion 131B may include n type impurities or both n and p type impurities to provide a second junction overlap region. According to an embodiment, the second junction overlap region of the channel portion 131A may include n type impurities as majority carriers. A height of the second junction overlap region may be defined from the contact surface of the doped semiconductor structure DPS in the first direction +DR1. The height of the second junction overlap region may be variously designed and controlled so as not to reach levels at which the plurality of word lines WL as described above with reference to FIG. 1 are disposed.

Referring to FIG. 3A, the oxidized buffer layer 141 may be interposed between the channel portion 131A of the semiconductor structure 131 and a core insulating layer 147 and may be covered by the capping portion 131B of the semiconductor structure 131. In an embodiment, the oxidized buffer layer 141 and the capping portion 131B are disposed in the first direction +DR1. For example, a top surface of the oxidized buffer layer 141 is covered by the capping portion 131B as shown in FIG. 3A. In an embodiment, the capping portion 131B covering the oxidized buffer layer 141 may be directly on the oxidized buffer layer 141. For example, the capping portion 131B covering the oxidized buffer layer 141 may be directly on a first surface (i.e., top surface) of the oxidized buffer layer 141 as shown in FIG. 3A. The oxidized buffer layer 141 may be provided by oxidizing a buffer layer which is formed when the semiconductor structure 131 is formed. The buffer layer may include a material having etch resistance against an etching material which is used to remove a gettering layer for removing a metal catalyst. According to an embodiment, the buffer layer may include at least one of nitrogen and carbon. As a result, the oxidized buffer layer 141 may also include an oxide material including at least one of nitrogen and carbon. According to an embodiment, the oxidized buffer layer 141 may include an oxide of silicon carbon nitride (SiCN), an oxide of silicon oxycarbide (SiOC), an oxide of silicon nitride (SiₓN_{y}), or an oxide of silicon oxynitride (SiON).

In addition, the oxidized buffer layer 141 may include a metal oxide which is formed by oxidizing the metal catalysts which are diffused into the buffer layer when the semiconductor structure 131 is formed. In an embodiment, the metal oxide may be trapped in the oxidized buffer layer 141. In an embodiment, the metal oxide may be within the oxidized buffer layer 141. The metal oxide may include an oxide of the metal catalyst which serves as a crystallization seed during crystallization using MIC. According to an embodiment, the metal oxide may include at least one of nickel oxide, silver oxide, gold oxide, copper oxide, aluminum oxide, tin oxide, and cadmium oxide.

The oxidized buffer layer 141 may be removed during manufacturing processes of the semiconductor memory device. As a result, as shown in FIG. 3B, the core insulating layer 147 may directly contact the channel portion 131A of the semiconductor structure 131.

Referring to FIGS. 3A and 3B, the memory layer ML may extend on the outer wall of the semiconductor structure 131 toward the gate stack structure GST. Though not shown, a portion of the memory layer ML may be penetrated by the doped semiconductor structure DPS shown in FIG. 2A or 2B, or the channel portion 131A of the semiconductor structure 131. As a result, a contact surface may be defined between the channel portion 131A and the doped semiconductor structure DPS shown in FIG. 2A or 2B.

A plurality of insulating layers 101 and a plurality of conductive layers 151 may be divided into the gate stack structures GST by a slit 161. The plurality of insulating layers 101 and the plurality of conductive layers 151 of each of the gate stack structures GST may be alternately stacked in the first direction +DR1 along a sidewall of the semiconductor structure 131.

The memory layer ML may include a tunnel isolation layer 125 interposed between the gate stack structure GST and the semiconductor structure 131, a data storage layer 123 interposed between the gate stack structure GST and the tunnel isolation layer 125, and a blocking insulating layer 121 interposed between the gate stack structure GST and the data storage layer 123. The tunnel isolation layer 125 may include an oxide such as a silicon dioxide (SiO₂). The data storage layer 123 may continuously extend in the first direction +DR1 or be separated into discrete data storage patterns in the first direction +DR1.

According to an embodiment, as shown in FIGS. 3A and 3B, the data storage layer 123 may continuously extend on the plurality of insulating layers 101 and the plurality of conductive layers 151 in the first direction +DR1. Though not shown, in another embodiment, the data storage layer 123 may be cut at the levels where the plurality of insulating layers 101 are disposed, and may be separated into a plurality of data storage patterns. The plurality of data storage patterns may be arranged at the levels where the plurality of conductive layers 151 are arranged. In other words, each of the data storage patterns may include the data storage layer 123 disposed between a conductive layer corresponding thereto and the semiconductor structure 131. The data storage layer 123 may include a material layer which stores data being changed, using Fowler-Nordheim tunneling. According to an embodiment, the data storage layer 123 may include a charge trap insulating layer, a floating gate layer, or an insulating layer including conductive nanodots. The charge trap insulating layer may include a silicon nitride layer. The data storage layer which includes a floating gate layer may be separated into a plurality of data storage patterns as described above. The data storage layer which includes a charge trap layer or an insulating layer including conductive nanodots may be separated into a plurality of data storage patterns, or may continuously extend in the first direction +DR1 as in the data storage layer 123 shown in FIG. 3A or 3B.

The blocking insulating layer 121 may include an oxide such as silicon dioxide (SiO₂), a high-k dielectric insulating material having a higher dielectric constant than the silicon dioxide, or the like. The high-k insulating material may include aluminum oxide, hafnium oxide, and the like.

As described above, in an embodiment, because the channel portion 131A of the semiconductor structure 131 includes the crystallized semiconductor material provided using MIC, the channel portion 131A may improve a channel current in the semiconductor structure 131.

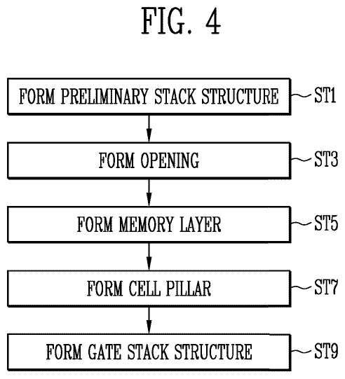

FIG. 4 is a flowchart illustrating manufacturing processes of a semiconductor memory device according to various embodiments of the present disclosure.

Referring to FIG. 4, manufacturing processes of the semiconductor memory device may include ST1 of forming a preliminary stack structure, ST3 of forming an opening, ST5 of forming a memory layer, ST7 of forming a cell pillar, and ST9 of forming a gate stack structure.

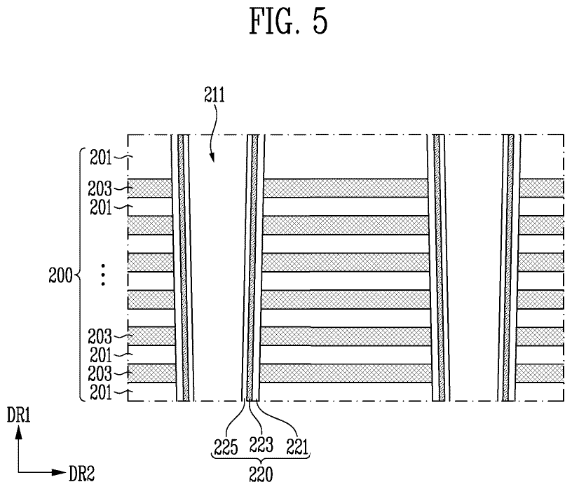

FIG. 5 is a cross-sectional diagram illustrating a preliminary stack structure 200, an opening 211, and a memory layer 220 according to an embodiment of the present disclosure.

Referring to FIG. 5, the preliminary stack structure 200 may be formed on a lower structure (not shown) through ST1 shown in FIG. 4. The preliminary stack structure 200 may be formed by stacking first material layers 201 and second material layers 203 alternately with each other. That is, the first material layer 201 may alternate with the second material layer 203. The plurality of first material layers 201 and the plurality of second material layers 203 may have a shape of a flat panel which extends in a second direction DR2 crossing the first direction DR1. The plurality of first material layers 201 may include an insulating material such as a silicon nitride layer and a silicon oxynitride layer. The plurality of second material layers 203 may include a conductive material or a sacrificial insulating material having etch selectivity with respect to the plurality of first material layers 201. According to an embodiment, the sacrificial insulating material may include a silicon nitride layer. Hereinafter, a method of manufacturing the semiconductor memory device will be described based on an embodiment in which the plurality of first material layers 201 include an insulating material and the plurality of second material layers 203 include a sacrificial insulating material. However, embodiments of the present disclosure are not limited thereto.

Though not shown in FIG. 5, in an embodiment, a lower structure may include the semiconductor substrate SUB including the plurality of transistors PTR shown in FIG. 2A and the doped semiconductor structure DPS shown in FIG. 2A. In another embodiment, the lower structure may be a sacrificial substrate which includes a silicon wafer.

Subsequently, the opening 211 which extends in the first direction DR1 to pass through the plurality of first material layers 201 and the plurality of second material layers 203 may be formed through ST3 shown in FIG. 4. As a result, a plurality of sidewalls of the plurality of first material layers 201 and the plurality of second material layers 203 may be exposed on an inner wall of the opening 211.

Hereinafter, the memory layer 220 may be formed through ST5 shown in FIG. 4. The memory layer 220 may extend in the first direction DR1 on the inner wall of the opening 211. According to an embodiment, ST5 may include forming a blocking insulating layer 221 on the inner wall of the opening 211, forming a data storage layer 223 on an inner wall of the blocking insulating layer 221, and forming a tunnel isolation layer 225 on an inner wall of the data storage layer 223. The blocking insulating layer 221 may include a silicon dioxide or a high-k insulating material having a higher dielectric constant than the silicon dioxide. The data storage layer 223 may include a charge trap insulating layer including a silicon nitride layer. The blocking insulating layer 221 may include a silicon dioxide (SiO 2) or the like.

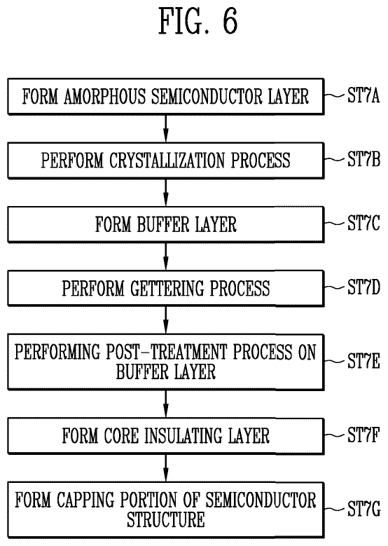

FIG. 6 is a flowchart illustrating an embodiment of ST7 shown in FIG. 4.

Referring to FIG. 6, ST7 shown in FIG. 4 may include forming an amorphous semiconductor layer at ST7A, forming a crystallization process at ST7B, forming a buffer layer at ST7C, performing a gettering process at ST7D, performing a post-treatment process on the buffer layer at ST7E, forming a core insulating layer at ST7F, and forming a capping portion of a semiconductor structure at ST7G.

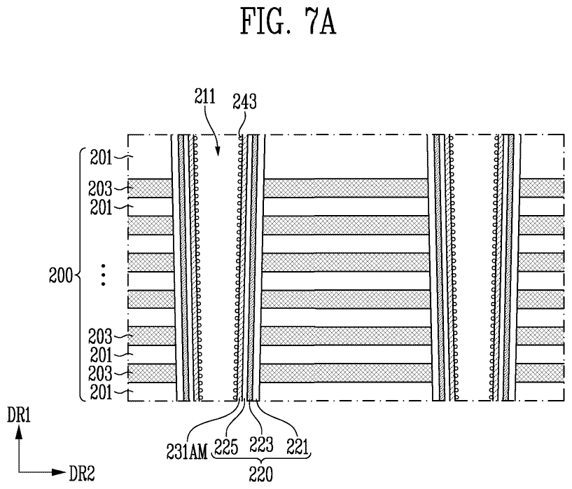

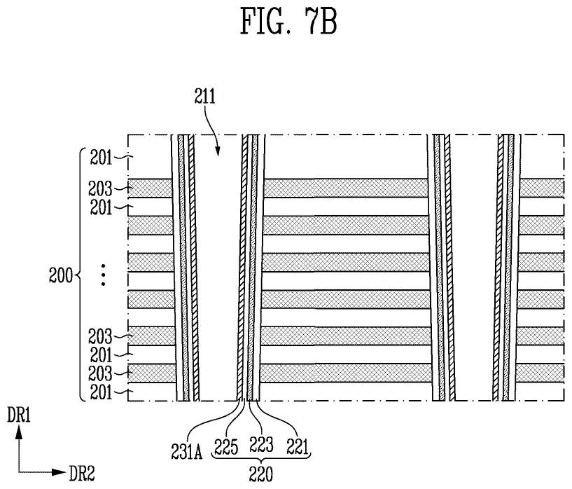

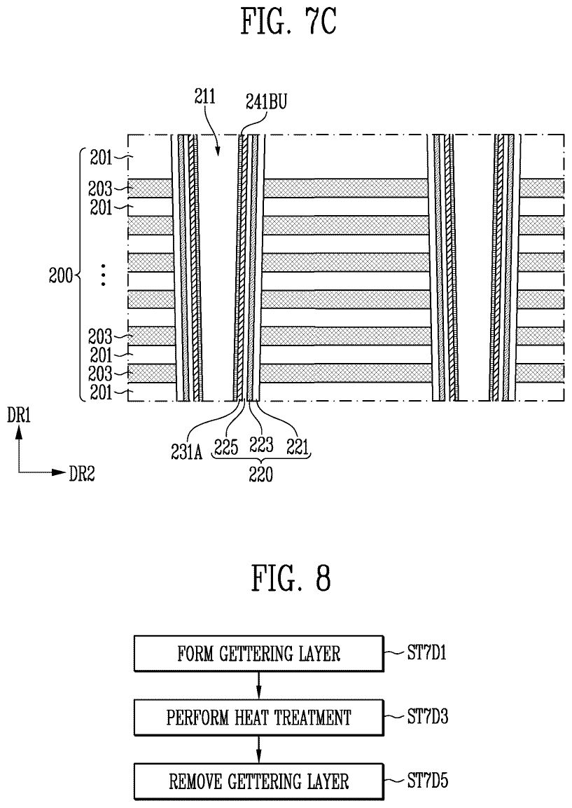

FIGS. 7A, 7B, and 7C are cross-sectional diagrams illustrating various embodiments of an amorphous semiconductor layer, a buffer layer, metal catalysts, and a crystalline semiconductor layer according to an embodiment of the present disclosure.

Referring to FIG. 7A, an amorphous semiconductor layer 231AM may be formed on an inner wall of the memory layer 220 through ST7A shown in FIG. 6. The amorphous semiconductor layer 231AM may include silicon (Si), germanium (Ge), or a mixture thereof. According to an embodiment, the amorphous semiconductor layer 231AM may include amorphous silicon.

Subsequently, ST7B shown in FIG. 6 may be performed. ST7B may be performed using a metal induced crystallization (MIC) method. According to an embodiment, referring to FIGS. 6 and 7A, ST7B may include forming metal catalysts 243 on an inner wall of the amorphous semiconductor layer 231AM. The metal catalysts 243 may serve as seeds for crystallization and be formed at a controlled density in line with a target grain size. The metal catalysts 243 may include at least one of nickel (Ni), silver (Ag), gold (Au), copper (Cu), aluminum (Al), tin (Sn), and cadmium (Cd). Referring to FIGS. 6 and 7B, “ST7B” may include a heat treatment process by which the amorphous semiconductor layer 231AM shown in FIG. 7A is crystallized into a crystalline semiconductor layer 231A. The metal catalysts 243 shown in FIG. 7A may be diffused into the amorphous semiconductor layer 231AM shown in FIG. 7A by heat treatment. The metal catalysts 243 diffused into the amorphous semiconductor layer 231AM may serve as crystallization seeds, and crystals may grow around the crystallization seeds in the amorphous semiconductor layer 231AM to thereby form the crystalline semiconductor layer 231A.

When, in an embodiment, the crystallization is performed using the metal catalysts 243, uniformity of a crystal size of the crystalline semiconductor layer 231A may be improved to thereby improve the operational reliability of the semiconductor memory device.

Referring to FIG. 7C, a buffer layer 241BU may be formed on an inner wall of the crystalline semiconductor layer 231A through ST7C shown in FIG. 6. Before the buffer layer 241BU is formed, a process of removing an oxide such as a natural oxide layer by a cleaning process may be further performed.

The buffer layer 241BU may include a material having etch resistance with respect to the etching material used during the process of removing the gettering layer at ST7D shown in FIG. 6. According to an embodiment, the buffer layer 241BU may include at least one of nitrogen and carbon. For example, the buffer layer 241BU may include silicon carbon nitride (SiCN), silicon oxycarbide (SiOC), silicon nitride (SiₓN_{y}) or silicon oxynitride (SiON).

The buffer layer 241BU may be formed on an inner wall of the crystalline semiconductor layer 231A and have a thickness ranging substantially from 5 Å to 10 Å. For example, when the thickness of the buffer layer 241BU is less than 5 Å, the buffer layer 241BU may be removed during a subsequent process of removing a gettering layer. On the other hand, in an embodiment, when the thickness of the buffer layer 241BU exceeds 10 Å, the efficiency of gettering the metal catalysts by the gettering layer may be decreased.

FIG. 8 is a flowchart illustrating an embodiment of ST7D shown in FIG. 6.

Referring to FIG. 8, ST7D shown in FIG. 6 may include forming a gettering layer at ST7D1, performing heat treatment at ST7D3, and removing the gettering layer at ST7D5. According to an embodiment, ST7D1, ST7D3, and ST7D5 may be performed when the crystalline semiconductor layer 231A is protected by the buffer layer 241BU as shown in FIG. 7C. Therefore, in an embodiment, even if ST7D1, ST7D3, and ST7D5 are repeated two or more times until the metal catalysts are reduced to a target amount or are completely removed, loss of the crystalline semiconductor layer 231A may be reduced or prevented.

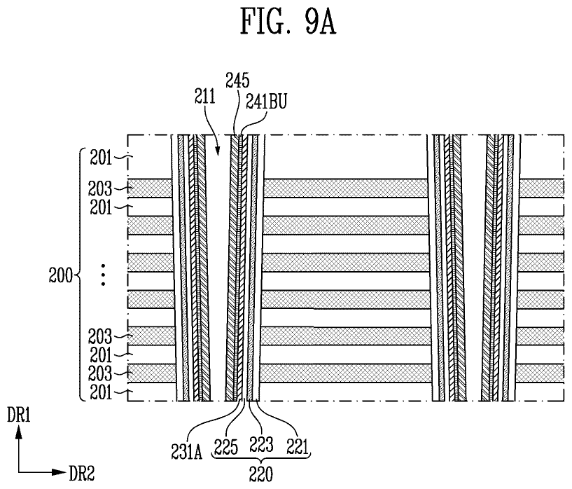

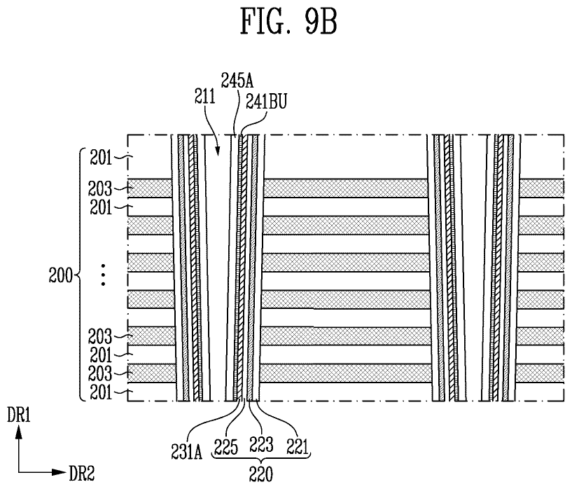

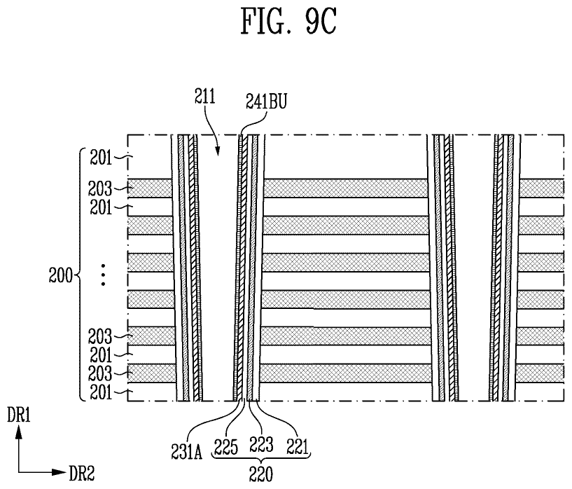

FIGS. 9A, 9B, and 9C are cross-sectional diagrams illustrating various embodiments of structures disposed in an opening according to processes as shown in FIG. 8.

Referring to FIG. 9A, a gettering layer 245 may be formed on an inner wall of the buffer layer 241BU through ST7D1 shown in FIG. 8. The gettering layer 245 may have etch selectivity with respect to the buffer layer 241BU and include a material having a smaller diffusion coefficient than the metal catalysts 243 shown in FIG. 7A. According to an embodiment, the gettering layer 245 may include at least one of silicon nitride (Si₃N₄) and amorphous silicon.

Referring to FIG. 9B, the metal catalysts remaining in the crystalline semiconductor layer 231A may be diffused into the gettering layer 245 shown in FIG. 9A by heat treatment through ST7D3 shown in FIG. 9A. As a result, the metal catalysts may be gettered in the gettering layer 245A after ST7D3.

Referring to FIG. 9C, the gettering layer 245A shown in FIG. 9B may be removed through ST7D5 shown in FIG. 8. The buffer layer 241BU may serve as an etch stop layer and an inner wall of the buffer layer 241BU may be exposed.

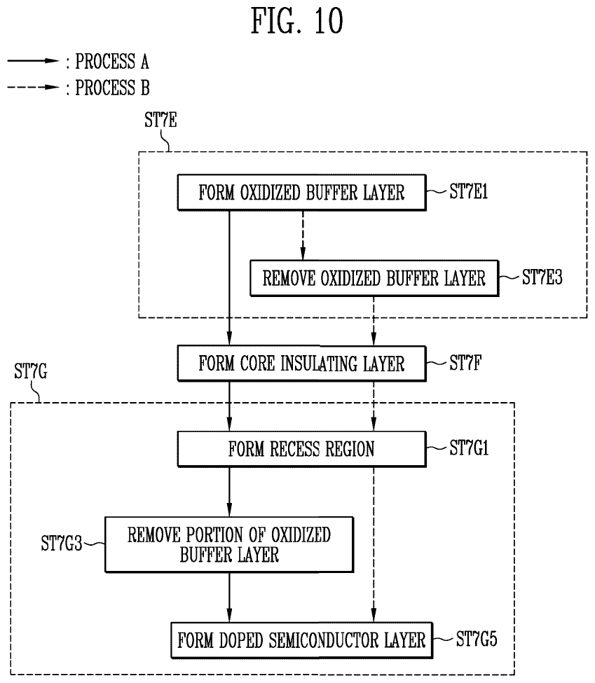

FIG. 10 is a flowchart illustrating embodiments for subsequent processes after ST7D shown in FIG. 6.

Referring to FIG. 10, the subsequent processes may be performed according to process A or process B after ST7D shown in FIG. 6.

Referring to the process A, after ST7D shown in FIG. 6, ST7E1 of forming the oxidized buffer layer, ST7F of forming a core insulating layer, ST7G1 of forming the recessed region of ST7G, ST7G3 of partially removing the oxidized buffer layer of ST7G, and ST7G5 of forming the doped semiconductor layer of ST7G may be sequentially formed.

Referring to the process B, after ST7D shown in FIG. 6, ST7E1 of forming the oxidized buffer layer of ST7E, ST7E3 of partially removing the oxidized buffer layer of ST7E, ST7F of forming core insulating layers, ST7G1 of forming the recessed region of ST7G, and ST7G5 of forming the doped semiconductor layer of ST7G may be sequentially formed.

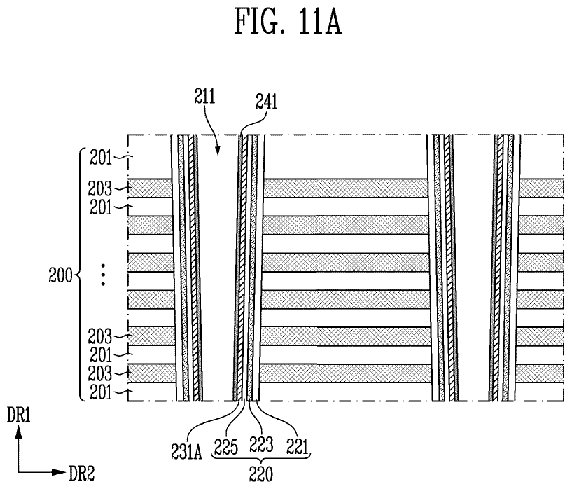

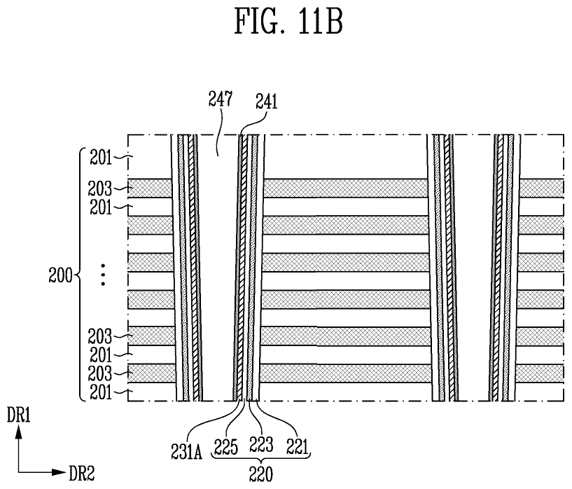

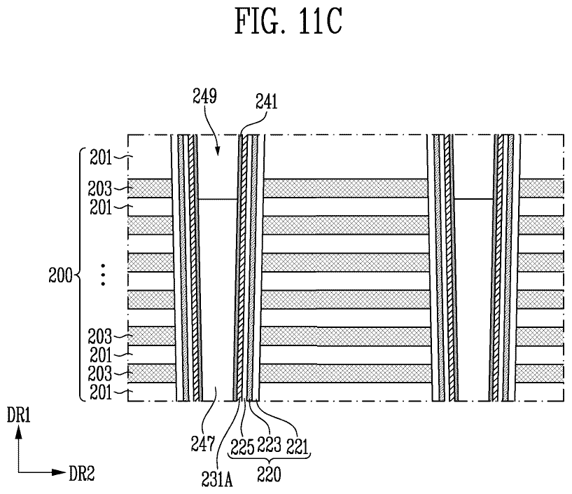

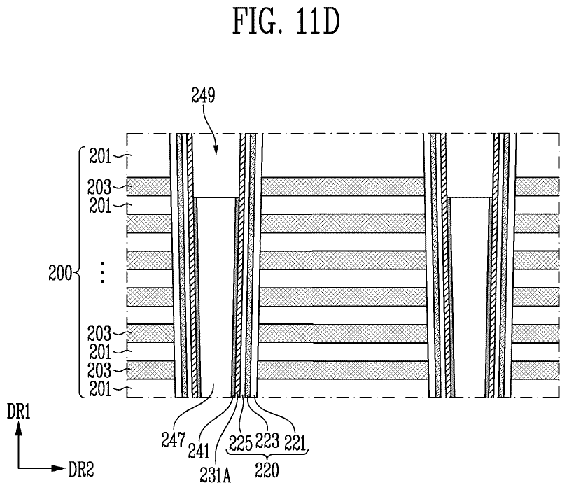

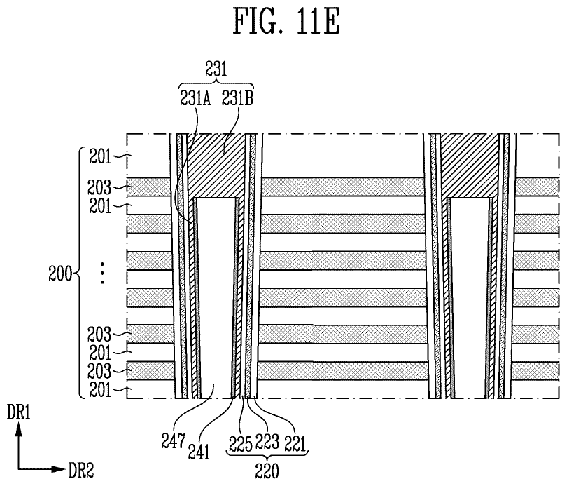

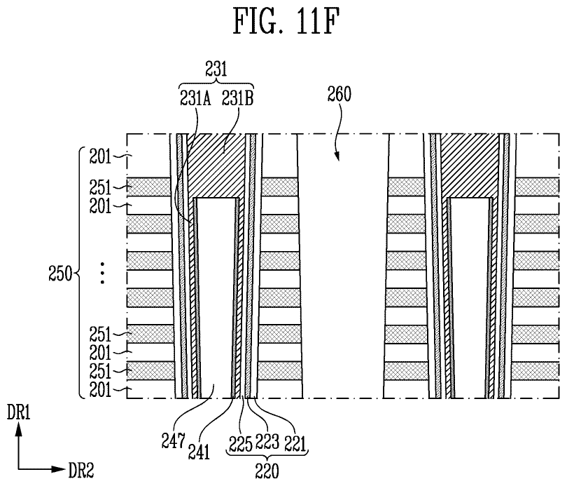

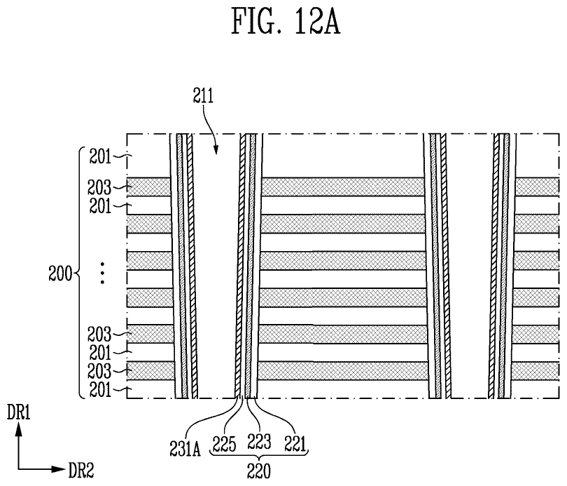

FIGS. 11A, 11B, 11C, 11D, and 11E are cross-sectional diagrams illustrating various embodiments of structures disposed in an opening according to the process A shown in FIG. 10, and FIG. 11F is a cross-sectional diagram illustrating various embodiments of a gate stack structure.

Referring to FIG. 11A, an oxidized buffer layer 241 may be formed by oxidizing the buffer layer 241BU shown in FIG. 9C through ST7E1 shown in FIG. 10. The buffer layer 241BU shown in FIG. 9C may include small amounts of metal catalysts diffused at ST7D3. As a result, the metal catalysts in the buffer layer may be oxidized through ST7E1 shown in FIG. 10. Accordingly, a metal oxide may be trapped in the oxidized buffer layer 241. In an embodiment, as the metal catalysts in the buffer layer are oxidized, current leakage resulting from the metal catalysts in the buffer layer may be reduced or prevented.

Referring to FIG. 11B, a core insulating layer 247 may be formed at a central area of an opening formed by the oxidized buffer layer 241 through ST7F shown in FIG. 10.

Referring to FIG. 11C, a recessed region 249 may be formed by removing a portion of the core insulating layer 247 through ST7G1 shown in FIG. 10. A portion of the oxidized buffer layer 241 may be exposed by the recessed region 249.

Referring to FIG. 11D, the exposed region of the oxidized buffer layer 241 may be removed through the recessed region 249 through ST7G3 shown in FIG. 10. As a result, the crystalline semiconductor layer 231A may be exposed.

Referring to FIG. 11E, the recessed region and the region from which the oxidized buffer layer 241 is removed may be filled with a doped semiconductor layer 231B through ST7G5 shown in FIG. 10. Subsequently, an additional process such as laser annealing for crystallization may be performed. The doped semiconductor layer 231B and a portion of the crystalline semiconductor layer 231A coupled thereto may form an integral semiconductor structure 231 without forming an interface. The doped semiconductor layer 231B and a portion of the crystalline semiconductor layer 231A coupled thereto may form a capping portion of the semiconductor structure 231, and another portion of the crystalline semiconductor layer 231A between the core insulating layer 247 and the memory layer 220 may form a channel portion of the semiconductor structure 231.

Referring to FIG. 11F, a slit 260 may be formed to pass through the plurality of first material layers 201 and the second material layers 203 as shown in FIG. 11E. According to an embodiment, when the second material layers 203 shown in FIG. 11E include a sacrificial insulating material, the plurality of second material layers 203 shown in FIG. 111E may be replaced by a plurality of third material layers 251 through the slit 260. The plurality of third material layers 251 may include a conductive material. The plurality of first material layers 201 and the plurality of third material layers 251 which are arranged alternately with each other in the first direction DR1 may form a gate stack structure 250.

In another embodiment, when the plurality of second material layers 203 shown in FIG. 11E include a conductive material, the plurality of first material layers 201 and the second material layers 203 shown in FIG. 11E may be divided into gate stack structures by the slit 260.

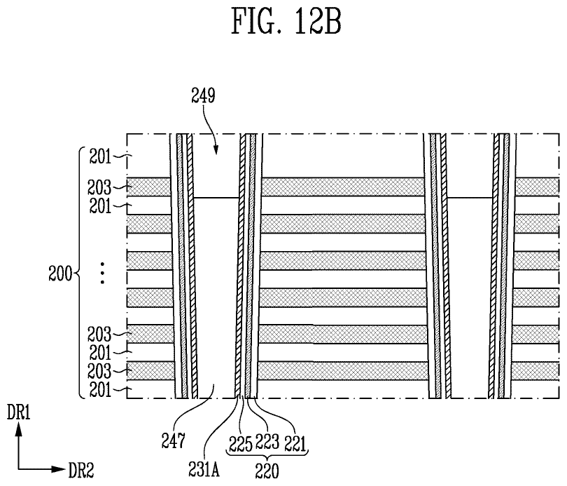

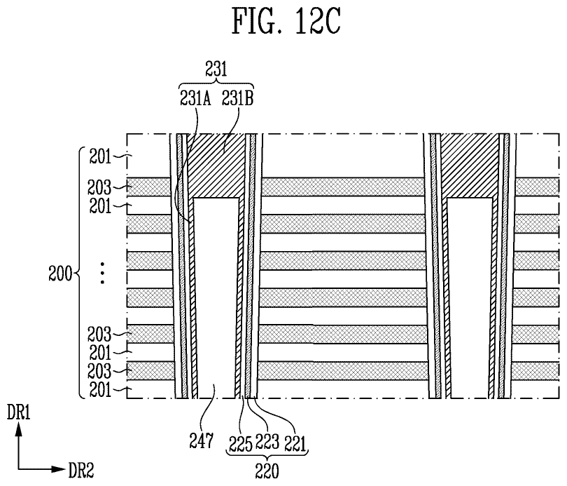

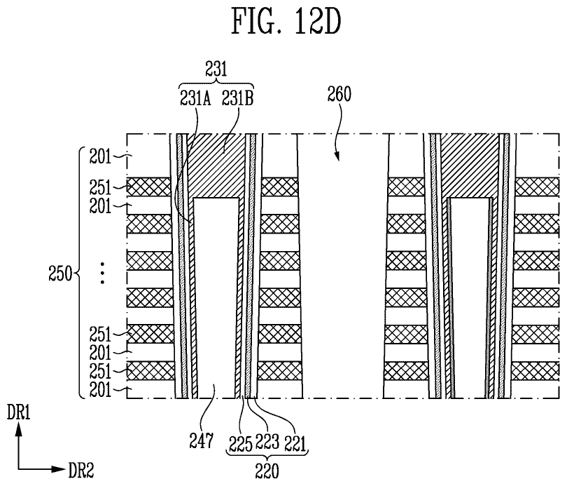

FIGS. 12A, 12B, and 12C are cross-sectional diagrams illustrating various embodiments of structures disposed in an opening according to the process B shown in FIG. 10, and FIG. 12D is a cross-sectional diagram illustrating various embodiments of a gate stack structure.

Before the process shown in FIG. 12A is performed, as described above with reference to FIG. 11A, the oxidized buffer layer 241 may be formed by oxidizing the buffer layer 241BU, shown in FIG. 9C, through ST7E1 shown in FIG. 10.

Referring to FIG. 12A, the oxidized buffer layer 241 shown in FIG. 11A may be removed through ST7E3 shown in FIG. 10. As a result, an inner wall of the crystalline semiconductor layer 231A may be exposed.

Referring to FIG. 12B, the core insulating layer 247 may be formed at a central area of an opening formed by the oxidized buffer layer 241 through ST7F shown in FIG. 10. Subsequently, the recessed region 249 may be formed by partially removing the core insulating layer 247 through ST7G1 shown in FIG. 10. A portion of the inner wall of the crystalline semiconductor layer 231A may be exposed by the recessed region 249.

Referring to FIG. 12C, the recessed region 249 shown in FIG. 12B may be filled with the doped semiconductor layer 231B through ST7G5 shown in FIG. 10. Subsequently, an additional process such as laser annealing for crystallization may be performed. The doped semiconductor layer 231B and the crystalline semiconductor layer 231A may form the integral semiconductor structure 231 without forming an interface. The doped semiconductor layer 231B and a portion of the crystalline semiconductor layer 231A coupled thereto may form a capping portion of the semiconductor structure 231, and another portion of the crystalline semiconductor layer 231A between the core insulating layer 247 and the memory layer 220 may form a channel portion of the semiconductor structure 231.

Referring to FIG. 12D, as described above with reference to FIG. 11F, a process of forming the slit 260 and a process of replacing the plurality of second material layers 203 shown in FIG. 12C by the plurality of third material layers 251 through the slit 260 may be performed. Accordingly, the gate stack structure 250 may be formed.

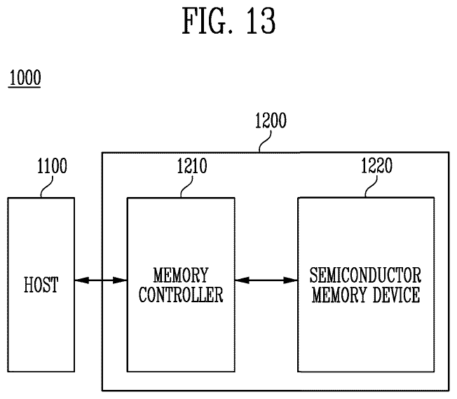

FIG. 13 is a block diagram illustrating an electronic system 1000 according to an embodiment of the present disclosure.

Referring to FIG. 13, the electronic system 1000 may include a computing system, a medical device, a communication device, a wearable device, or a memory system. The electronic system 1000 may include a host 1100 and a storage device 1200.

The host 1100 may store data in the storage device 1200, or may read the stored data from the storage device 1200 on the basis of an interface. The interface may include one or more of a Double Data Rate (DDR) interface, a Universal Serial Bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics interface (IDE), a Firewire interface, a Universal Flash Storage (UFS) interface, and a Nonvolatile Memory express (NVMe) interface.

The storage device 1200 may include a memory controller 1210 and a semiconductor memory device 1220. According to an embodiment, the storage device 1200 may be a solid state drive (SSD), a universal serial bus (USB) memory, or the like.

The memory controller 1210 may store data in the semiconductor memory device 1220, or may read data stored in the semiconductor memory device 1220 in response to control of the host 1100.

The semiconductor memory device 1220 may include a single memory chip or a plurality of memory chips. The semiconductor memory device 1220 may store data or output stored data in response to control of the memory controller 1210.

In an embodiment, the semiconductor memory device 1220 may be a non-volatile memory device. In an embodiment, the semiconductor memory device 1220 may include a core insulating layer, a semiconductor structure including a channel portion extending on a side wall of the core insulating layer and a capping portion covering one surface of the core insulating layer and coupled to the channel portion, a plurality of conductive layers and a plurality of insulating layers stacked alternately with each other, the plurality of conductive layers and the plurality of insulating layers surrounding a side wall of the semiconductor structure, and a memory layer disposed between each of the plurality of conductive layers and the semiconductor structure.

According to an embodiment of the present disclosure, a semiconductor structure may be formed with a semiconductor layer that is crystallized using metal catalysts to thereby improve a channel current, so that an operating speed of a semiconductor memory device may be increased.

According to an embodiment of the present disclosure, because the crystalized semiconductor layer is protected by a buffer layer, the semiconductor structure may be prevented from being damaged, thereby improving an operating reliability of a semiconductor memory device.

According to an embodiment of the present disclosure, a leakage current caused by the metal catalysts in the buffer layer may be reduced or prevented by oxidizing the buffer layer, so that operational reliability of a semiconductor memory device may be improved.

What is claimed is:

1. A semiconductor memory device, comprising:
a core insulating layer extending in a first direction;
a semiconductor structure including a channel portion extending in the first direction on a side wall of the core insulating layer and including a capping portion coupled to the channel portion, the capping portion covering a top surface of the core insulating layer, in the first direction;
an oxidized buffer layer interposed between the channel portion of the semiconductor structure and the core insulating layer, the oxidized buffer layer including a metal oxide;
a plurality of conductive layers and a plurality of insulating layers alternately stacked with each other in the first direction, each of the plurality of conductive layers and the plurality of insulating layers surrounding a side wall of the semiconductor structure; and
a memory layer disposed between each of the plurality of conductive layers and the semiconductor structure.

2. The semiconductor memory device of claim 1, wherein the semiconductor structure includes polycrystalline silicon.

3. The semiconductor memory device of claim 1, wherein the oxidized buffer layer includes at least one of nitrogen and carbon.

4. The semiconductor memory device of claim 1, wherein the oxidized buffer layer includes an oxide of silicon carbon nitride (SiCN), an oxide of silicon oxycarbide (SiOC), an oxide of silicon nitride (SiₓN_{y}), or an oxide of silicon oxynitride (SiON).

5. The semiconductor memory device of claim 1, wherein a top surface of the oxidized buffer layer is covered by the capping portion of the semiconductor structure, in the first direction.

6. The semiconductor memory device of claim 1, wherein the metal oxide is within the oxidized buffer layer.

7. The semiconductor memory device of claim 1, wherein the metal oxide includes one or more of nickel oxide, silver oxide, gold oxide, copper oxide, aluminum oxide, tin oxide, and cadmium oxide.

8. A method of manufacturing a semiconductor memory device, the method comprising:
stacking a plurality of first material layers and a plurality of second material layers stacked on top of each other in a first direction, each of the plurality of first material layers and each of the plurality of second material layers alternating with each other;
forming an opening extending in the first direction to pass through the plurality of first material layers and the plurality of second material layers;
forming a memory layer on an inner wall of the opening;
forming an amorphous semiconductor layer on an inner wall of the memory layer;
forming metal catalysts on an inner wall of the amorphous semiconductor layer;
crystalizing the amorphous semiconductor layer into a crystalline semiconductor layer;
forming a buffer layer on an inner wall of the crystalline semiconductor layer;
performing a gettering process on the metal catalysts; and
forming an oxidized buffer layer by oxidizing the buffer layer exposed after the gettering process.

9. The method of claim 8, wherein the gettering process of the metal catalysts is performed by repeating following processes at least twice:
forming a gettering layer on an inner wall of the buffer layer;
performing heat treatment such that the metal catalysts are gettered in the gettering layer; and
removing the gettering layer to expose the buffer layer after the heat treatment.

10. The method of claim 9, wherein during the heat treatment, the metal catalysts are diffused into the buffer layer, and
during the oxidizing of the buffer layer, the metal catalysts are oxidized in the buffer layer.

11. The method of claim 9, wherein the buffer layer includes a material having etch resistance with respect to an etching material used to remove the gettering layer.

12. The method of claim 9, wherein the gettering layer includes at least one of silicon nitride (Si₃N₄) and amorphous silicon.

13. The method of claim 8, wherein the buffer layer includes at least one of nitrogen and carbon.

14. The method of claim 8, wherein the buffer layer includes an oxide of silicon carbon nitride (SiCN), an oxide of silicon oxycarbide (SiOC), an oxide of silicon nitride (SiₓN_{y}), or an oxide of silicon oxynitride (SiON).

15. The method of claim 8, wherein the buffer layer is formed on an inner wall of the crystalline semiconductor layer and has a thickness ranging substantially from 5 Å to 10 Å.

16. The method of claim 8, wherein the metal catalysts include one or more of nickel (Ni), silver (Ag), gold (Au), copper (Cu), aluminum (Al), tin (Sn), and cadmium (Cd).

17. The method of claim 8, further comprising removing the oxidized buffer layer to expose an inner wall of the crystalline semiconductor layer.

18. The method of claim 17, further comprising, after completely removing the oxidized buffer layer:
forming a core insulating layer at a central area of the opening formed by the crystalline semiconductor layer;
forming a recess region by partially removing the core insulating layer to expose a portion of the inner wall of the crystalline semiconductor layer; and
filling the recess region with a doped semiconductor layer.

19. The method of claim 17, further comprising:
forming a core insulating layer at a central area of the opening formed by the oxidized buffer layer; and
forming a recess region by removing a portion of the core insulating layer to expose a portion of the oxidized buffer layer,
wherein the oxidized buffer layer is removed through the recess region.

20. The method of claim 19, further comprising filling the recess region and an area, from which the oxidized buffer layer is removed, with a doped semiconductor layer.

21. The method of claim 8, further comprising:
forming a slit through the plurality of first material layers and the plurality of second material layers; and
replacing the plurality of second material layers by a plurality of third material layers through the slit.

22. The method of claim 21, wherein:
the plurality of first material layers include an insulating material,
the plurality of second material layers include a sacrificial insulating material, and
the plurality of third material layers include a conductive material.
